(19) United States
(12) Patent Application Publication
(10) Pub. No.: US 2026/0037455 A1
(43) Pub. Date: Feb. 5, 2026

(54) APPARATUSES, METHODS, AND SYSTEMS FOR PERFORMING MODIFIED REFRESH SEQUENCE FOLLOWING SELF-REFRESH EXIT

(71) Applicant: Micron Technology, Inc., Boise, ID (US)

(72) Inventors: Wonjun Choi, Boise, ID (US); Hyun Yoo Lee, Boise, ID (US)

(73) Assignee: Micron Technology, Inc., Boise, ID (US)

(21) Appl. No.: 19/269,842

(22) Filed: Jul. 15, 2025

Related U.S. Application Data
(60) Provisional application No. 63/677,914, filed on Jul. 31, 2024.

(51) Int. Cl. G06F 13/16; G06F 3/06

(52) U.S. Cl. CPC G06F 13/1636; G06F 3/0604; G06F 3/0659; G06F 3/0673; G06F 2213/16

(57) ABSTRACT

Apparatuses, systems, and methods for performing a modified refresh following self-refresh exit are disclosed. A circuit of a memory device provides a self-refresh indicator signal at an active level after self-refresh exit and before performance of a next refresh operation. Responsive to the self-refresh indicator signal is at the active level, the next refresh operation can be a modified refresh sequence, which may comprise two normal refreshes and no targeted refreshes. The modified refresh sequence can be performed as part of a self-refresh operation or an auto-refresh operation. The disclosed technology may allow for modified operation of a memory controller, such that no additional refresh command is required following self-refresh exit.

### CROSS-REFERENCE TO RELATED APPLICATIONS

This application claims the filing benefit of U.S. Provisional Application No. 63/677,914, filed Jul. 31, 2024. This application is incorporated by reference herein in its entirety and for all purposes.

### BACKGROUND

This disclosure relates generally to semiconductor devices, and more specifically to semiconductor memory devices. For example, disclosed embodiments may relate to volatile memory, such as dynamic random-access memory (DRAM). Information may be stored on individual memory cells of the memory device as a physical signal (e.g., a charge on a capacitive element). During a read operation the physical signal (e.g., the charge) may be coupled to a conductive element to cause a change in voltage. That change in voltage may be amplified and read out to input/output terminals of the device. A write operation may reverse the process, receiving a signal at the terminals and providing a voltage to the memory cell (e.g., to charge the capacitor).

Various types of memory devices exist, including random access memory (RAM), read only memory (ROM), dynamic RAM (DRAM), synchronous dynamic RAM (SDRAM), ferroelectric RAM (FeRAM), magnetic RAM (MRAM), resistive RAM (RRAM), flash memory, phase change memory (PCM), and others. Memory devices may be volatile or non-volatile. Non-volatile memory, e.g., FeRAM, may maintain their stored logic state for extended periods of time even in the absence of an external power source. Volatile memory devices, e.g., DRAM, may lose their stored state when disconnected from an external power source.

In some cases, a memory device may perform refresh operations to read and restore the state of volatile memory cells to mitigate the potential loss of state information. For example, some volatile memory cells, such as DRAM cells, include a capacitor for storing the state of the memory cell, and such memory cells may need to be periodically refreshed.

### BRIEF DESCRIPTION OF THE DRAWINGS

FIG. 1 is a block diagram of a memory device according to an embodiment of the disclosure.

FIG. 2 is a timing diagram illustrating refresh operations performed by a memory device.

FIG. 3A is a timing diagram illustrating refresh operations performed by a memory device according to an embodiment of the disclosure.

FIG. 3B is a timing diagram illustrating refresh operations performed by a memory device according to an embodiment of the disclosure.

FIG. 4 is a block diagram illustrating a self-refresh indicator circuit according to an embodiment of the disclosure.

### DETAILED DESCRIPTION

The following description of certain embodiments is merely illustrative in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Information in a memory device is stored in memory cells of a memory array. The information is conveyed as voltages along various internal signal lines. For example, a first voltage may represent a logical high, while a second voltage may represent a logical low. Memory devices may perform refresh operations to prevent loss of the information. For example, memory cells may be refreshed by reading and restoring (e.g., restoring back to a first stored level) the state of the memory cells to mitigate the potential loss of state information due to, for example, charge leakage. For example, DRAM cells may include a capacitor for storing the state of the memory cell, and such memory cells may need to be refreshed to compensate for charge leakage from the capacitor over time. One or more refresh operations may be performed in response to receiving a refresh command from, for example, a controller or a host device, such as an auto-refresh command. Additionally, refresh operations may be performed in a self-refresh mode based on internal logic of a memory device in response to a self-refresh entry command.

There is a need for technologies that allow for more flexible refresh operations. For example, it would be advantageous to allow for a modified refresh sequence upon self-refresh exit.

Embodiments disclosed herein include apparatuses, methods, and systems for performing a modified refresh sequence upon self-refresh exit. A self-refresh indicator circuit according to the disclosed technology provides a self-refresh indicator signal at an active level responsive to a self-refresh exit. When the self-refresh indicator signal is at the active level, a next refresh operation (e.g., a self-refresh operation or an auto-refresh operation) may be a modified refresh sequence, which omits targeted refreshes. For example, the modified refresh sequence may include two normal refreshes and no targeted refreshes. The modified refresh sequence may be performed as a normally scheduled refresh operation or a self-refresh operation, rather than requiring that an additional refresh be issued by a controller upon self-refresh exit. The modified refresh sequence may be performed as a first refresh operation after self-refresh exit. Upon completion of the modified refresh sequence, the self-refresh indicator signal may be deactivated, and subsequent refresh operations may be performed as normal refresh operations, such as refresh sequences that comprise a normal refresh and a plurality of targeted refreshes.

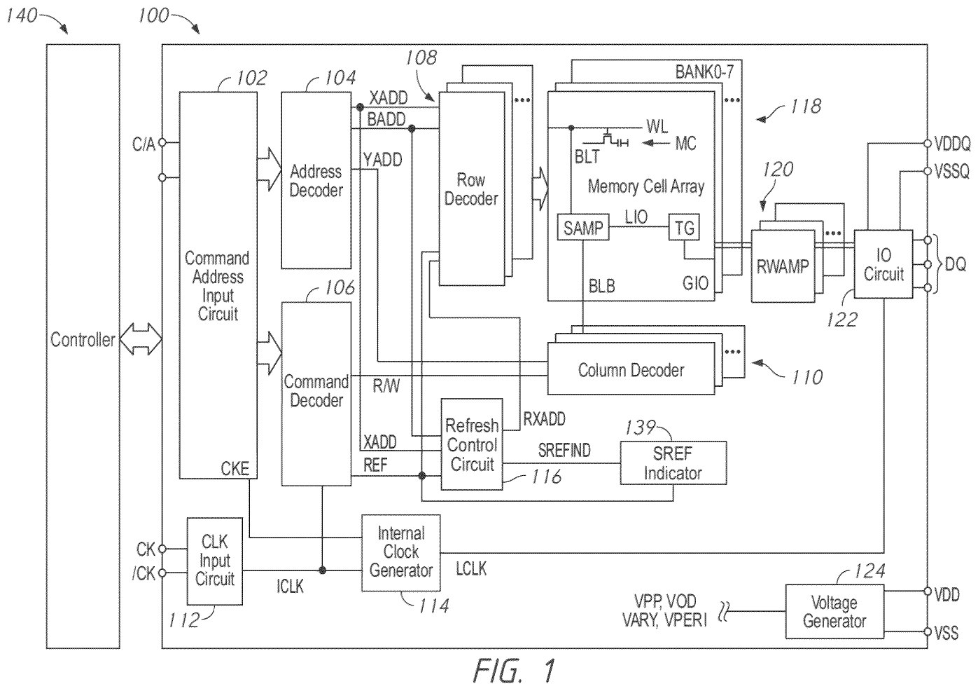

FIG. 1 is a block diagram of a memory device 100 according to an embodiment of the disclosure. The memory device 100 may be, for example, a DRAM device integrated on a single semiconductor chip. The memory device 100 is coupled to a controller 140, and the memory device 100 and the controller 140 may comprise a memory system.

The memory device 100 includes a memory array 118. The memory array 118 is shown as including a plurality of memory banks. In the embodiment of FIG. 1, the memory array 118 is shown as including eight memory banks BANK0-BANK7. More or fewer banks can be included in the memory array 118 of other embodiments. Each memory bank includes a plurality of word lines WL, a plurality of bit lines BLT and BLB, and a plurality of memory cells MC arranged at intersections of the plurality of word lines WL and the plurality of bit lines BLT (and BLB). The selection of the word line WL is performed by a row decoder 108 and the selection of the bit lines BLT, BLB is performed by a column decoder 110. In the embodiment of FIG. 1, the row decoder 108 includes a respective row decoder for each memory bank and the column decoder 110 includes a respective column decoder for each memory bank. The bit lines BLT, BLB are coupled to a respective sense amplifier (SAMP). Read data from the bit line BLT (or BLB) is amplified by the sense amplifier SAMP, and transferred to read/write amplifiers 120 over local data lines (LIO), transfer gate (TG), and global data lines (GIO). Conversely, write data outputted from the read/write amplifiers 120 is transferred to the sense amplifier SAMP over the complementary main data lines GIO, the transfer gate TG, and the complementary local data lines LIO, and written in the memory cell MC coupled to the bit line BLT (or BLB).

The memory device 100 may employ a plurality of external terminals that include command and address (C/A) terminals coupled to a command and address bus to receive commands and addresses from the controller 140, clock terminals to receive clocks CK and/CK from the controller 140, data terminals DQ coupled to a data bus to provide data to the controller 140, and power supply terminals to receive power supply potentials VDD, VSS, VDDQ, and VSSQ at respective conductive lines of the memory device 100.

The clock terminals are supplied with external clocks CK and/CK by the controller 140 that are provided to an input circuit 112. The external clocks may be complementary. The input circuit 112 generates an internal clock ICLK based on the CK and/CK clocks. The ICLK clock is provided to the command decoder 106 and to an internal clock generator 114. The internal clock generator 114 provides various internal clocks LCLK based on the ICLK clock. The LCLK clocks may be used for timing operation of various internal circuits. For example, the internal data clocks LCLK are provided to the input/output circuit 122 to time operation of circuits included in the input/output circuit 122, for example, to data receivers to time the receipt of write data. The input/output circuit 122 may include a number of interface connections, each of which may be couplable to one of the DQ pads (e.g., the solder pads which may act as external connections to the memory device 100).

The C/A terminals may be supplied with memory addresses by the controller 140. The memory addresses supplied to the C/A terminals are transferred, via a command/address input circuit 102, to an address decoder 104. The address decoder 104 receives the address and supplies a decoded row address XADD to the row decoder 108 and supplies a decoded column address YADD to the column decoder 110. The column decoder 110 may provide a column select signal, which may select one or more of the sense amplifiers SAMP. The address decoder 104 may also supply a decoded bank address BADD, which may indicate the bank of the memory array 118 containing the decoded row address XADD and column address YADD. The C/A terminals may be supplied with commands by the controller 140. Examples of commands include refresh commands (e.g., auto-refresh commands) including self-refresh commands (e.g., self-refresh entry commands, self-refresh exit commands), activate commands for activating pages of memory, access commands for accessing the memory, such as read commands for performing read operations and write commands for performing write operations, as well as other commands and operations. The activate and access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations. For example, the command decoder 106 may provide a row command signal to select a word line and a column command signal to select a bit line.

The memory device 100 may receive an access command from the controller 140 which is a read command. When activate and read commands are received, and a bank address, a row address, and a column address are timely supplied with the activate and read commands, read data is read from memory cells in the memory array 118 corresponding to the row address and column address. The read command is received by the command decoder 106, which provides internal commands so that read data from the memory array 118 is provided to the read/write amplifiers 120. The read data is provided along the data bus and output to outside from the data terminals DQ via the input/output circuit 122.

The memory device 100 may receive an access command from the controller 140 which is a write command. When activate and write commands are received, and a bank address, a row address, and a column address are timely supplied with the activate and write commands, write data supplied to the data terminals DQ is provided along the data bus and written to a memory cells in the memory array 118 corresponding to the row address and column address. The write command is received by the command decoder 106, which provides internal commands so that the write data is received by data receivers in the input/output circuit 122. Write clocks may also be provided to the external clock terminals for timing the receipt of the write data by the data receivers of the input/output circuit 122. The write data is supplied via the input/output circuit 122 to the read/write amplifiers 120, and by the read/write amplifiers 120 to the memory array 118 to be written into the memory cell MC.

The memory device 100 may receive commands causing it to carry out one or more refresh operations, such as a self-refresh entry command to cause performance of self-refresh operations as part of a self-refresh mode or an auto-refresh command to cause performance of auto-refresh operations. A refresh operation may include various refresh sequences, such as sequences that include normal refreshes and/or targeted refreshes. When an external signal indicates a refresh command, the command decoder 106 may decode the refresh command and provide the refresh signal REF (e.g., a self-refresh signal or an auto-refresh signal). The refresh signal REF is supplied to the refresh control circuit 116, and the refresh control circuit 116 may provide internal refresh commands to cause performance of refresh operations, such as internal refresh commands to cause an auto-refresh operation or a self-refresh operation. The refresh control circuit 116 supplies a refresh row address RXADD to the row decoder 108, which may refresh one or more word lines WL indicated by the refresh row address RXADD.

As part of a normal refresh, which may be a CBR refresh, the refresh control circuit 116 generates the refresh address RXADD based on sequence logic. For example, each refresh address RXADD may be based on a previous refresh address such as RXADD(i)=RXADD(i−1)+1. The sequence logic may include an address counter which counts through the row addresses of the bank. In some embodiments, one or more bits of the refresh address RXADD may be masked compared to a full row address XADD. In this way, a plurality of word lines that share the non-masked portion in common may be refreshed at one time.

The refresh control circuit 116 also causes performance of targeted refreshes, which may be row hammer refreshes to refresh victim rows associated with aggressor rows. For example, when a Per Row Activation Counting (PRAC) value exceeds a threshold value, the address associated with that PRAC value is identified as an aggressor row and added to an aggressor queue. When a targeted refresh is performed, the refresh control circuit 116 generates a refresh address RXADD based on the address in the queue. The targeted refresh addresses reflect the addresses of word lines which have a physical relationship with the aggressor word line, such as the word lines adjacent to the aggressor and/or the word lines adjacent to those word lines. In various embodiments, a targeted refresh may include a set of operations based on a single address in the queue. For example, if HitXADD is the aggressor address stored in the queue, and the adjacent word lines are being refreshed, then the targeted refresh includes refreshing refresh addresses RXADD=HitXADD+1, HitXADD−1, and resetting HitXADD. If the word lines adjacent to the adjacent word lines are also being refreshed, then the targeted refresh includes refreshing refresh addresses RXADD=HitXADD+1, HitXADD−1, HitXADD+2, HitXADD−2, and resetting HitXADD.

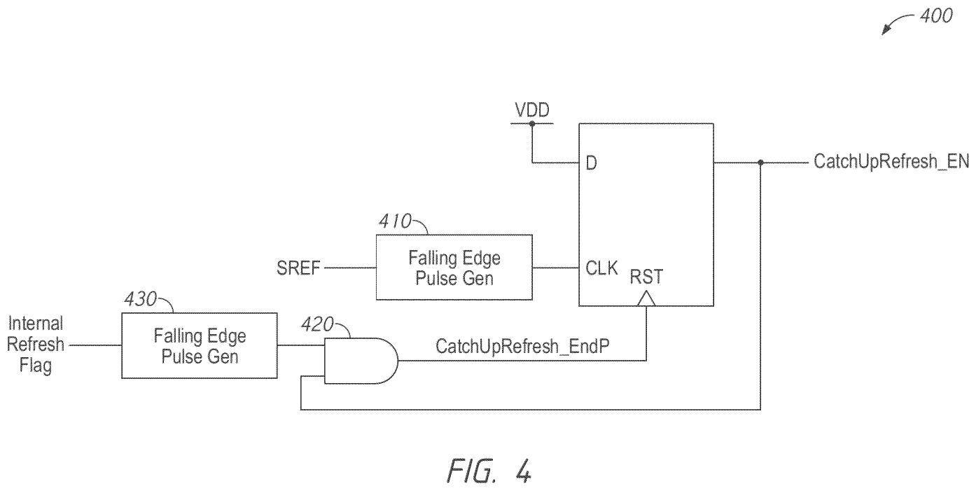

In various embodiments, the refresh control circuit 116 causes performance of a modified refresh sequence following self-refresh exit. While conventional technologies may require that the controller 140 must issue an additional refresh command upon self-refresh exit in addition to normally scheduled refresh commands, the disclosed technology may omit this additional refresh command and instead cause performance of the modified refresh sequence for a first refresh operation following the self-refresh exit. In some examples, the modified refresh sequence comprises two normal refreshes and no targeted refreshes. In various embodiments, a self-refresh exit command is received from the controller 140 and decoded by the command decoder 106 to cause the memory device 100 to exit a self-refresh mode, and a self-refresh indicator circuit 139 (e.g., 400 of FIG. 4) detects the self-refresh exit. Responsive to the self-refresh exit, and before performance of a next refresh operation, the self-refresh indicator circuit 139 provides a self-refresh indicator signal SREFIND at an active level to the refresh control circuit 116. When the self-refresh indicator signal SREFIND is at the active level, the refresh control circuit 116 causes performance of the modified refresh sequence for the next refresh operation (e.g., a self-refresh operation or an auto-refresh operation). Responsive to performance of the next refresh operation, the self-refresh indicator signal SREFIND is deactivated, and subsequent refresh operations may be normal refresh sequences.

As used herein, a self-refresh exit command can refer to a sequence of events that, when performed, cause the memory device 100 to exit a self-refresh mode. For example, self-refresh exit can be triggered when a chip select signal transitions from low to high and stays high for at least a threshold time (e.g., tCSH_SRExit), when a CA bus is driven high for at least a threshold time (e.g., tCASRX) prior to the chip select signal transitioning high, and/or when three no-operation (NOP) commands are received. The self-refresh exit command can also require that one or more timing delay criteria must be satisfied.

Power supply terminals of the memory device 100 are supplied with power supply potentials VDD and VSS. The power supply potentials VDD and VSS are supplied to an internal voltage generator circuit 124. The internal voltage generator circuit 124 generates various internal potentials VPP, VOD, VARY, VPERI, and the like based on the power supply potentials VDD and VSS supplied to the power supply terminals. The power supply terminals are also supplied with power supply potential VDDQ. The power supply potentials VDDQ and VSS are supplied to the input/output circuit 122. The power supply potential VDDQ supplied to the power supply terminals may be the same potentials as the power supply potential VDD supplied to the power supply terminals. The power supply potential VDD supplied to the power supply terminals are used for the input/output circuit 122 so that power supply noise generated by the input/output circuit 122 does not propagate to the other circuit blocks.

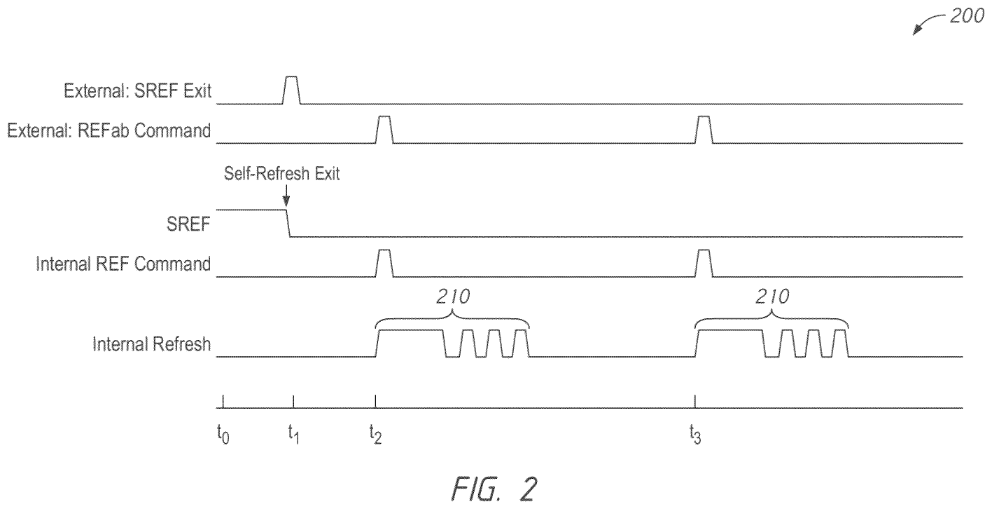

FIG. 2 is a timing diagram 200 illustrating refresh operations performed by a memory device. The timing diagram 200 illustrates operations that may be performed using a conventional memory system, such as a memory system operated in accordance with the Double Data Rate 5 Synchronous Dynamic Random-Access Memory (DDR5 SDRAM) standard maintained by the JEDEC Solid State Technology Association, or a similar standard.

At a time t₀, the memory device is in a self-refresh mode, as indicated by the self-refresh indicator SREF being at an active level. At a time t₁, the memory device receives a self-refresh exit command SREF Exit from a controller, and the memory device exits the self-refresh mode responsive to the self-refresh exit command SREF Exit, as indicated by the self-refresh indicator SREF transitioning to an inactive level.

At a time t₂, the memory device receives a refresh command REFab command from a controller, which may be an auto-refresh command. The refresh command REFab command received at time t₂ may be received due to a requirement in an applicable standard (e.g., the DDR5 standard) that one additional refresh must be issued upon self-refresh exit in addition to normally scheduled refresh commands.

Responsive to the refresh command REFab command received at time t₂, the memory device generates an internal refresh command Internal Ref command (e.g., using a refresh control circuit), and the memory device performs refresh operations Internal Refresh. The refresh operations Internal Refresh can comprise a refresh sequence 210. For example, conventional systems may perform a refresh sequence 210 comprising one normal refresh and a plurality of targeted refreshes (e.g., three targeted refreshes), as shown in the timing diagram 200. As described herein, the normal refresh can be performed according to sequence logic of a refresh control circuit, and the targeted refreshes can be, for example, row hammer refreshes performed on target rows (e.g., victim rows) based on identifying an aggressor row. While the refresh sequence 210 is shown as comprising one normal refresh and three targeted refreshes, other combinations of normal refreshes and targeted refreshes may be performed.

At a time t₃, the memory device receives another refresh command REFab command. The refresh command REFab command received at the time t₃ causes an internal refresh command Internal Ref command, which causes performance of another refresh sequence 210. The refresh command REFab command received at the time t₃ may be a normally scheduled refresh command.

It would be advantageous to have memory devices that can be operated more flexibly. For example, there may be little advantage to performing targeted refreshes in a memory that has just exited a self-refresh mode because, for example, it is unlikely that there will have been many recent access operations to cause a row hammer problem. Accordingly, it would be beneficial to allow for modified refresh sequences for a memory that has exited the self-refresh mode.

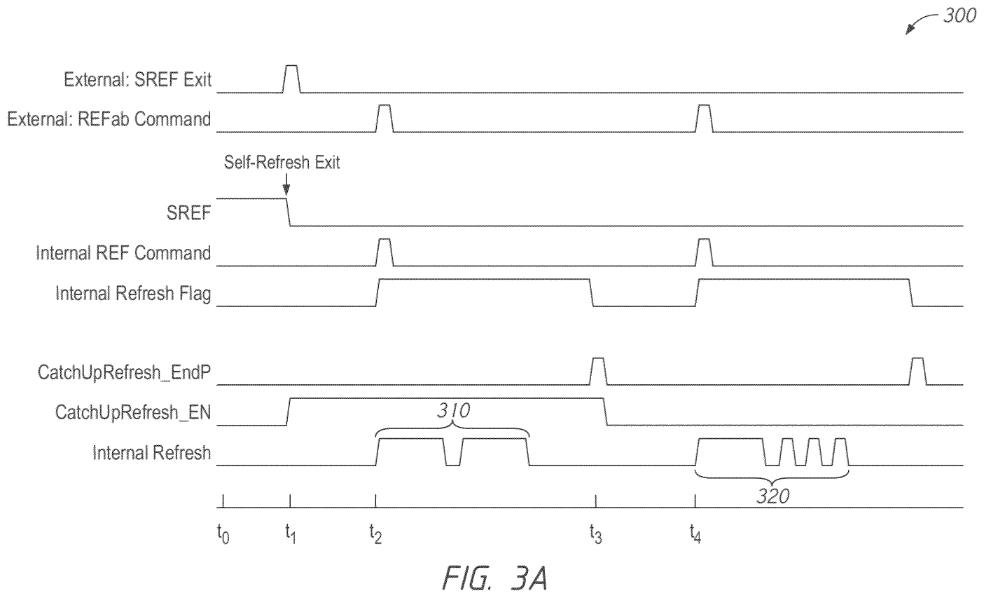

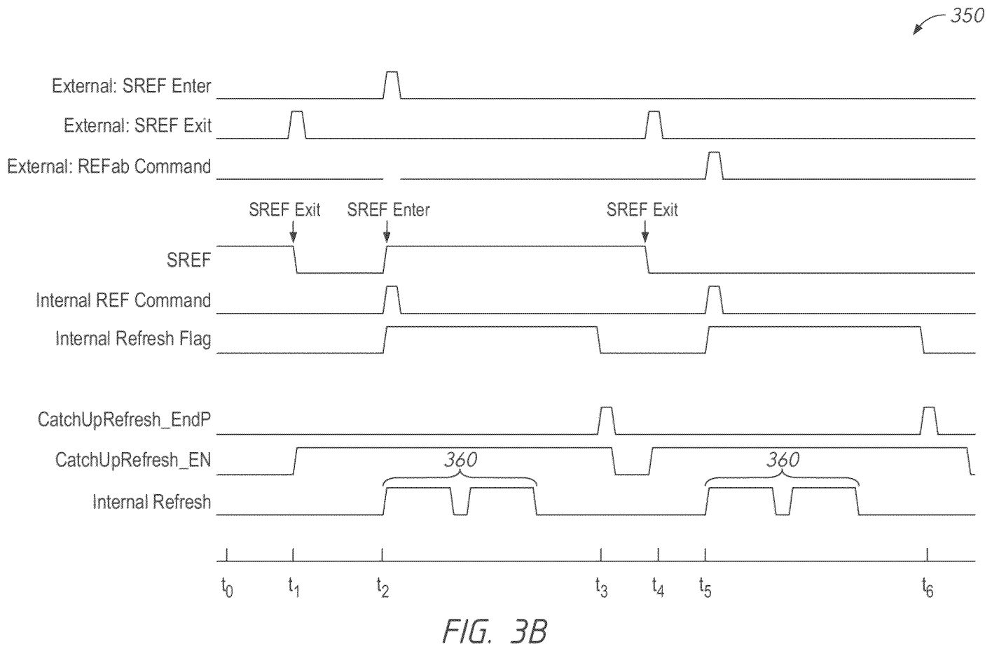

FIG. 3A is a timing diagram 300 illustrating refresh operations performed by a memory device according to an embodiment of the disclosure. In the illustrated example, the memory device is configured to perform a modified refresh sequence 310 responsive to a first refresh command after self-refresh exit. The memory device can be, for example, the memory device 100 of FIG. 1. The memory device includes a refresh control circuit (e.g., 116 of FIG. 1) and a self-refresh indicator circuit (e.g., 139 of FIG. 1 or 400 of FIG. 4).

At a time t₀, the memory device is in a self-refresh mode, as indicated by the self-refresh indicator SREF being at an active level. At a time t₁, the memory device receives a self-refresh exit command SREF Exit from a controller, and the memory device exits the self-refresh mode responsive to the self-refresh exit command SREF Exit, as indicated by the self-refresh indicator SREF transitioning to an inactive level.

Responsive to exiting the self-refresh mode, a self-refresh indicator signal CatchUpRefresh_EN is provided at an active level (e.g., by a self-refresh indicator circuit). For example, the self-refresh indicator SREF is provided to a falling edge pulse generator (e.g., 410 of FIG. 4), and the falling edge pulse generator generates a pulse to trigger the self-refresh indicator signal CatchUpRefresh_EN when the self-refresh indicator SREF is deactivated. The self-refresh indicator signal CatchUpRefresh_EN is provided at the active level to indicate that the memory device has exited the self-refresh mode and no self-refresh operations have been completed subsequent to the self-refresh exit.

At a time t₂, the memory device receives a refresh command REFab command from a controller, which may be an auto-refresh command. Unlike the example of FIG. 2, the refresh command REFab command received at time t₂ may be a normally scheduled refresh command, and not an additional refresh command issued upon self-refresh exit.

Responsive to the received refresh command REFab command, the memory device generates an internal refresh command Internal Ref command (e.g., using a refresh control circuit), and the memory device sets a flag Internal Refresh Flag. The memory device performs a refresh operation Internal Refresh responsive to the internal refresh command Internal Ref command. When the self-refresh indicator signal CatchUpRefresh_EN is at the active level, the refresh operation Internal Refresh comprises a modified refresh sequence 310, unlike the refresh sequence 210 illustrated with reference to FIG. 2. For example, the modified refresh sequence 310 can comprise two normal refreshes and no targeted refreshes. In various embodiments, the self-refresh indicator signal CatchUpRefresh_EN is provided at the active level by a self-refresh indicator circuit and to a refresh control circuit, such that the refresh control circuit causes performance of the modified refresh sequence when the self-refresh indicator signal CatchUpRefresh_EN is at the active level.

At a time t₃, Internal Refresh Flag is deactivated to indicate completion of the refresh operation. Deactivation of Internal Refresh Flag, together with the self-refresh indicator signal CatchUpRefresh_EN at the active level, may deactivate the self-refresh indicator signal CatchUpRefresh_EN. For example, Internal Refresh Flag may be provided to a falling edge pulse generator, such that the deactivation of Internal Refresh Flag triggers a pulse. This pulse and the self-refresh indicator signal CatchUpRefresh_EN are provided to an AND gate, which resets the self-refresh indicator signal CatchUpRefresh_EN responsive to the pulse and the CatchUpRefresh_EN at the active level. The output of the AND gate may be reset signal CatchUpRefresh_EndP, which causes deactivation of the self-refresh indicator signal CatchUpRefresh_EN.

At a time t₄, the memory device receives another refresh command REFab command, which causes an internal refresh command Internal REF command. When the self-refresh indicator signal CatchUpRefresh_EN is not at the active level, the memory performs a normal refresh sequence 320 (e.g., 210 of FIG. 2) responsive to the internal refresh command Internal REF command. The normal refresh sequence 320 can comprise a normal refresh and three targeted refreshes.

FIG. 3B is a timing diagram 350 illustrating refresh operations performed by a memory device according to an embodiment of the disclosure. In the illustrated example, the memory device is configured to perform a modified refresh sequence 360 (e.g., 310 of FIG. 3) responsive to a first refresh command after self-refresh exit. The memory device can be, for example, the memory device 100 of FIG. 1. The memory device includes a refresh control circuit (e.g., 116 of FIG. 1) and a self-refresh indicator circuit (e.g., 139 of FIG. 1 or 400 of FIG. 4).

At a time t₀, the memory device is in a self-refresh mode, as indicated by the self-refresh indicator SREF being at an active level. At a time t₁, the memory device receives a self-refresh exit command SREF Exit from a controller, and the memory device exits the self-refresh mode responsive to the self-refresh exit command SREF Exit, as indicated by the self-refresh indicator SREF transitioning to an inactive level. Responsive to exiting the self-refresh mode, a self-refresh indicator signal CatchUpRefresh_EN is provided at an active level (e.g., by a self-refresh indicator circuit). For example, the self-refresh indicator SREF is provided to a falling edge pulse generator (e.g., 410 of FIG. 4), and the falling edge pulse generator generates a pulse to trigger the self-refresh indicator signal CatchUpRefresh_EN when the self-refresh indicator SREF is deactivated. The self-refresh indicator signal CatchUpRefresh_EN is provided at the active level to indicate that the memory device has exited the self-refresh mode and no self-refresh operations have been completed subsequent to the self-refresh exit.

At a time t₂, the memory device receives a self-refresh entry command SREF Enter, which causes the memory device to again enter the self-refresh entry mode, as indicated by the self-refresh indicator SREF being provided at the active level. In the self-refresh entry mode, an internal refresh command Internal REF command is provided according to internal logic of the memory device (e.g., in a refresh control circuit). Additionally, a flag Internal Refresh Flag is set during performance of a refresh operation Internal Refresh performed responsive to the internal refresh command Internal REF command. The refresh operation can be a modified refresh sequence 360, which is performed when the self-refresh indicator signal CatchUpRefresh_EN is provided at the active level. Unlike conventional technologies, no refresh operations are performed between the self-refresh refresh exit (e.g., at time t₁) and the self-refresh entry (e.g., at time t₂). Additionally, the modified refresh sequence 360 can be performed as a first refresh operation after self-refresh exit, regardless of whether the refresh operation is a self-refresh operation or an auto-refresh operation.

At a time t₃, the flag Internal Refresh Flag is deactivated responsive to completion of the refresh operation, and the self-refresh indicator signal CatchUpRefresh_EN is deactivated responsive to the reset signal CatchUpRefresh_EndP (e.g., generated as described with reference to FIG. 3A).

At a time t₄, the memory device again receives a self-refresh exit command SREF Exit from a controller, and the memory device exits the self-refresh mode responsive to the self-refresh exit command SREF Exit, as indicated by the self-refresh indicator SREF transitioning to an inactive level.

Responsive to exiting the self-refresh mode, the self-refresh indicator signal CatchUpRefresh_EN is provided at the active level (e.g., by a self-refresh indicator circuit).

At a time t₅, the memory device receives a refresh command REFab command from a controller, which may be an auto-refresh command. Unlike the example of FIG. 2, the refresh command REFab command received at time t₅ may be a normally scheduled refresh command, and not an additional refresh command issued upon self-refresh exit. Responsive to the received refresh command REFab command, the memory device generates an internal refresh command Internal Ref command (e.g., using a refresh control circuit), and the memory device sets the flag Internal Refresh Flag. The memory device performs a refresh operation Internal Refresh responsive to the internal refresh command Internal Ref command. When the self-refresh indicator signal CatchUpRefresh_EN is at the active level, the refresh operation Internal Refresh comprises the modified refresh sequence 360.

At a time t₀, the flag Internal Refresh Flag is deactivated to indicate completion of the refresh operation. Deactivation of Internal Refresh Flag, together with the self-refresh indicator signal CatchUpRefresh_EN at the active level, may deactivate the self-refresh indicator signal CatchUpRefresh_EN.

Subsequent refresh operations (not shown) may be normal refresh sequences (e.g., 210 of FIG. 2) when the self-refresh indicator signal CatchUpRefresh_EN is not provided at the active level.

FIG. 4 is a block diagram illustrating a self-refresh indicator circuit 400 according to an embodiment of the disclosure. For example, the self-refresh indicator circuit 400 of FIG. 4 can be the self-refresh indicator circuit 139 of the memory device 100 of FIG. 1. The self-refresh indicator circuit 400 provides a self-refresh indicator signal CatchUpRefresh_EN (e.g., CatchUpRefresh_EN, as described with refers to FIGS. 3A & 3B) to indicate that a memory device has exited a self-refresh mode, and no refresh operations have been completed after the self-refresh exit.

The self-refresh indicator circuit 400 receives a voltage VDD. During operation, the self-refresh indicator circuit 400 receives, at a falling edge pulse generator 410, a self-refresh signal SREF. The SREF signal is at an active level responsive to a self-refresh command received by the memory device. The self-refresh command causes the memory device to enter a self-refresh mode, and the self-refresh signal SREF remains at the active level until the memory device exits the self-refresh mode. The self-refresh signal SREF is deactivated responsive to a self-refresh exit command, which causes the memory device to exit the self-refresh mode. The deactivation of the self-refresh signal SREF causes the falling edge pulse generator 410 to generate a pulse.

The pulse from the falling edge pulse generator 410 causes the self-refresh indicator signal CatchUpRefresh_EN to be provided at an active level. The self-refresh indicator signal CatchUpRefresh_EN is provided at the active level to a refresh control circuit (e.g., SREFIND provided to the refresh control circuit 116 of FIG. 1). When the refresh control circuit receives an internal refresh command and the self-refresh indicator signal CatchUpRefresh_EN at the active level, the refresh control circuit will cause a next refresh operation to be a modified refresh sequence (e.g., as shown with reference to FIGS. 3A and 3B), which may include two normal refreshes and no targeted refreshes.

The self-refresh indicator signal CatchUpRefresh_EN is also provided to an AND gate 420 of the self-refresh indicator circuit 400. The AND gate 420 also receives the output of falling edge pulse generator 430. The falling edge pulse generator 430 receives flag Internal Refresh Flag, which is provided at an active level during performance of a refresh operation. For example, Internal Refresh Flag is provided at an active level responsive to an internal refresh command (e.g., an internal command to cause performance of an auto-refresh operation or a self-refresh operation), and Internal Refresh Flag is deactivated upon completion of a refresh operation (e.g., a refresh sequence). When Internal Refresh Flag is deactivated, a pulse is generated by falling edge pulse generator 430. When the AND gate 420 receives this pulse and the self-refresh indicator signal CatchUpRefresh_EN at an active level, the AND gate 420 generates an output CatchUpRefresh_EndP, which deactivates the self-refresh indicator signal CatchUpRefresh_EN. When the self-refresh indicator signal CatchUpRefresh_EN is deactivated (i.e., when the self-refresh indicator signal CatchUpRefresh_EN is not provided to the refresh control circuit at the active level), the refresh control circuit causes performance of normal refresh sequences (e.g., 210 of FIG. 2 or 320 of FIG. 3A), and not modified refresh sequences (e.g., 310 of FIG. 3A or 360 of FIG. 3B). The normal refresh sequences may comprise a normal refresh and three targeted refreshes.

As used herein, an activation of a signal may refer to any portion of a signal waveform that a circuit responds to. For example, if a circuit responds to a rising edge, then a signal switching from a low level to a high level may be an activation. One example type of activation is a pulse, where a signal switches from a low level to a high level for a period of time, and then back to the low level. This may trigger circuits which respond to rising edges, falling edges, and/or signals being at a high logical level. One of skill in the art should understand that although embodiments may be described with respect to a particular type of activation used by a particular circuit (e.g., active high), other embodiments may use other types of activation (e.g., active low).

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a memory device comprising:
a self-refresh indicator circuit configured to provide a self-refresh indicator signal at an active level after the memory device exits a self-refresh mode and before performance of a refresh operation; and
a refresh control circuit configured to cause performance of the refresh operation responsive to a refresh command when the self-refresh indicator signal is at the active level.

2. The apparatus of claim 1, wherein the refresh operation comprises at least one normal refresh, and wherein the refresh operation does not include a targeted refresh.

3. The apparatus of claim 2, wherein the at least one normal refresh is to refresh one or more word lines identified based on sequence logic of the refresh control circuit, and wherein the targeted refresh is to refresh one or more victim word lines associated with an aggressor word line.

4. The apparatus of claim 1, wherein the refresh operation is a first refresh operation after the memory device exits the self-refresh mode.

5. The apparatus of claim 1, wherein the refresh command is a normally scheduled refresh command.

6. The apparatus of claim 1, wherein the refresh command is a self-refresh command, and wherein the refresh control circuit is configured to cause performance of the refresh operation in the self-refresh mode responsive to the self-refresh command.

7. The apparatus of claim 1, wherein the refresh command is an auto-refresh command.

8. The apparatus of claim 1, further comprising:
a controller configured to provide the refresh command.

9. A system comprising:
a command/address (CA) bus;
a memory controller configured to provide a refresh command via the CA bus; and
a memory configured to:
receive the refresh command from the memory controller via the CA bus; and
perform a refresh sequence responsive to the refresh command, wherein the refresh sequence does not include a targeted refresh when the refresh command is a first refresh command received after self-refresh exit.

10. The system of claim 9, wherein the refresh sequence comprises two normal refreshes.

11. The system of claim 9, wherein the first refresh command received after self-refresh exit is a normally scheduled refresh command.

12. The system of claim 9, wherein the memory includes a self-refresh indicator circuit configured to provide a self-refresh indicator signal at an active level responsive to the self-refresh exit and before performance of the refresh sequence.

13. The system of claim 9, wherein the refresh command is an auto-refresh command.

14. The system of claim 9, wherein the refresh command is a self-refresh command.

15. A method comprising:
receiving a refresh command;
detecting a self-refresh indicator signal; and
performing a refresh operation responsive to the refresh command, wherein the refresh operation comprises a first refresh sequence when the self-refresh indicator signal is at an active level or a second refresh sequence when the self-refresh indicator signal is at an inactive level.

16. The method of claim 15, further comprising:
exiting a self-refresh mode; and
providing the self-refresh indicator signal at the active level responsive to exiting the self-refresh mode.

17. The method of claim 15, further comprising:
deactivating the self-refresh indicator signal responsive to performing the first refresh sequence.

18. The method of claim 15, wherein the first refresh sequence comprises two normal refreshes and no targeted refreshes.

19. The method of claim 15, wherein the refresh command is an auto-refresh command.

20. The method of claim 15, wherein the refresh command is a self-refresh command.

21. The method of claim 15, wherein the self-refresh indicator signal is at the active level after self-refresh exit and before performance of a next refresh operation.

22. A method comprising:
providing a self-refresh entry command to cause a memory to enter a self-refresh mode;
providing a self-refresh exit command to cause the memory to exit the self-refresh mode; and
providing, after the self-refresh exit command, normally scheduled refresh commands without providing an additional refresh command responsive to the self-refresh exit command.

23. The method of claim 22, further comprising:
providing a second self-refresh entry command after the self-refresh exit command to cause the memory to enter the self-refresh mode a second time, wherein no refresh commands are provided between the self-refresh exit command and the second self-refresh entry command.

24. The method of claim 22, wherein the self-refresh exit command comprises a sequence including a chip select (CS) signal at a high logic level and a plurality of no-operation (NOP) commands.

25. The method of claim 22, wherein the normally scheduled refresh commands comprise auto-refresh commands.
